(19) United States
(12) Patent Application Publication
(10) Pub. No.: US 2014/0145091 A1
(43) Pub. Date: May 29, 2014

(54) ELECTRON BEAM EXPOSURE APPARATUS

(71) Applicant: SAMSUNG ELECTRONICS CO., LTD., Suwon-si (KR)

(72) Inventor: Dong-Seok Nam, Yongin-si (KR)

(73) Assignee: SAMSUNG ELECTRONICS CO., LTD., Suwon-si (KR)

(21) Appl. No.: 14/085,035

(22) Filed: Nov. 20, 2013

(30) Foreign Application Priority Data
Nov. 27, 2012 (KR) 10-2012-0135002

(51) Int. Cl. H01J 37/317; H01J 37/147; H01J 37/06

(52) U.S. Cl. CPC H01J 37/3177; H01J 37/06; H01J 37/1471
USPC 250/397; 250/396 R

(57) ABSTRACT

An electron beam exposure apparatus may include a plurality of electron guns, a condenser lens, a position-adjusting unit and an aperture plate. The electron guns may emit electron beams to a substrate. The condenser lens may be arranged between the electron guns and the substrate to concentrate the electron beams. The position-adjusting unit may individually adjust positions of the electron guns to provide the concentrated electron beam with a uniform intensity. The aperture plate may be arranged between the substrate and the condenser lens. The aperture plate may have a plurality of apertures through which the concentrated electron beams are incident.

### CROSS-REFERENCE TO RELATED APPLICATION

Korean Patent Application No. 10-2012-0135002, filed on Nov. 27, 2012, in the Korean Intellectual Property Office, and entitled: “Electron Beam Exposure Apparatus,” is incorporated by reference herein in its entirety.

### BACKGROUND

1. Field

Example embodiments relate to an electron beam exposure apparatus. More particularly, example embodiments relate to an electron beam exposure apparatus including a plurality of electron guns configured to emit electron beams.

2. Description of the Related Art

An exposure apparatus may be used for forming a pattern on a semiconductor substrate. The exposure apparatus may expose a resist film on the semiconductor substrate using a light, an electron beam, an ion beam, an extreme ultraviolet light, etc., to form a resist pattern.

The electron beam exposure apparatus may include a single electron gun and a single aperture. An electron beam emitted from the single electron gun may pass through the single aperture to form a single shot. The single shot may then be irradiated to the resist film. However, a long time for manufacturing a highly integrated semiconductor device may be required using the single shot.

A method of solving the above-mentioned problem may include emitting a plurality of the electron beams from a plurality of the electron guns, and controlling the electron beams.

### SUMMARY

Example embodiments provide an electron beam exposure apparatus that may provide a multi-shot having uniform intensity.

According to some example embodiments, there may be provided an electron beam exposure apparatus. The electron beam exposure apparatus may include a plurality of electron guns, a condenser lens, a position-adjusting unit and an aperture plate. The electron guns may emit electron beams to a substrate. The condenser lens may be arranged between the electron guns and the substrate to concentrate the electron beams. The position-adjusting unit may individually adjust positions of the electron guns to provide the concentrated electron beams with uniform intensity. The aperture plate may be arranged between the substrate and the condenser lens. The aperture plate may have a plurality of apertures through which the concentrated electron beams may pass.

In example embodiments, the position-adjusting unit may include a first position-adjusting member configured to move the electron guns in a first horizontal direction.

In example embodiments, the position-adjusting unit may further include a second position-adjusting member configured to move the electron guns in a second horizontal direction substantially perpendicular to the first horizontal direction.

In example embodiments, the position-adjusting unit may further include a third position-adjusting member configured to move the electron guns in a vertical direction.

In example embodiments, the position-adjusting unit may include a micrometer.

In example embodiments, the position-adjusting unit may further include a piezoelectric element.

In example embodiments, the position-adjusting unit may include only a piezoelectric element.

In example embodiments, the electron beam exposure apparatus may further include a detector configured to detect the intensities of the electron beams passing through the apertures.

In example embodiments, the electron beam exposure apparatus may further include a controller configured to store the intensities of the electron beams and to control operations of the position-adjusting unit based on the intensities of the electron beams.

According to some example embodiments, there may be provided an electron beam exposure apparatus. The electron beam exposure apparatus may include a plurality of electron guns, a condenser lens, a position-adjusting unit, an aperture plate, a projector lens, a detector and a controller. The electron guns may emit electron beams to a substrate. The condenser lens may be arranged between the electron guns and the substrate to concentrate the electron beams. The position-adjusting unit may individually adjust positions of the electron guns to provide the concentrated electron beams with uniform intensity. The aperture plate may be arranged between the substrate and the condenser lens. The aperture plate may have a plurality of apertures through which the concentrated electron beams may pass. The detector may detect the intensities of the electron beams passing through the apertures. The controller may store the intensities of the electron beams. The controller may control operations of the position-adjusting unit based on the intensities of the electron beams.

In example embodiments, the position-adjusting unit may include a first position-adjusting member configured to move the electron guns in a first horizontal direction, a second position-adjusting member configured to move the electron guns in a second horizontal direction substantially perpendicular to the first horizontal direction, and a third position-adjusting member configured to move the electron guns in a vertical direction.

In example embodiments, the position-adjusting unit may include a micrometer.

In example embodiments, the position-adjusting unit may further include a piezoelectric element.

According to some example embodiments, there may be provided an electron beam exposure apparatus. The electron beam exposure apparatus may include a plurality of electron guns, a condenser lens, a positioning adjusting unit, and an aperture plate. The electron guns may emit electron beams to a stage. The condenser lens may be arranged between the electron guns and the stage, the condenser lens concentrating the electron beam. The position-adjusting unit may be configured to individually adjust positions of the electron guns to provide the concentrated electron beam with a uniform intensity. The aperture plate may be between the stage and the condenser lens, the aperture plate having a plurality of apertures on which the concentrated electron beam is incident.

The plurality of electron guns may be arranged in a 2-dimensional array.

### BRIEF DESCRIPTION OF THE DRAWINGS

Example embodiments will be more clearly understood from the following detailed description taken in conjunction with the accompanying drawings. FIGS. 1 to 8 represent non-limiting, example embodiments as described herein.

FIG. 1 illustrates a perspective view of an electron beam exposure apparatus in accordance with example embodiments;

FIG. 2 illustrates a plan view of a position-adjusting unit of the electron beam exposure apparatus in FIG. 1;

FIG. 3 illustrates a front view of the position-adjusting unit of the electron beam exposure apparatus in FIG. 1;

FIG. 4 illustrates a perspective view of intensity distributions of electron beams emitted from electron guns of the electron beam exposure apparatus in FIG. 1;

FIGS. 5 and 6 illustrate cross-sectional views of operations for providing a concentrated electron beam with uniform intensity in accordance with example embodiments; and

FIGS. 7 and 8 illustrate cross-sectional views of operations for providing a concentrated electron beam with uniform intensity in accordance with example embodiments.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings herein.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, example embodiments will be explained in detail with reference to the accompanying drawings.

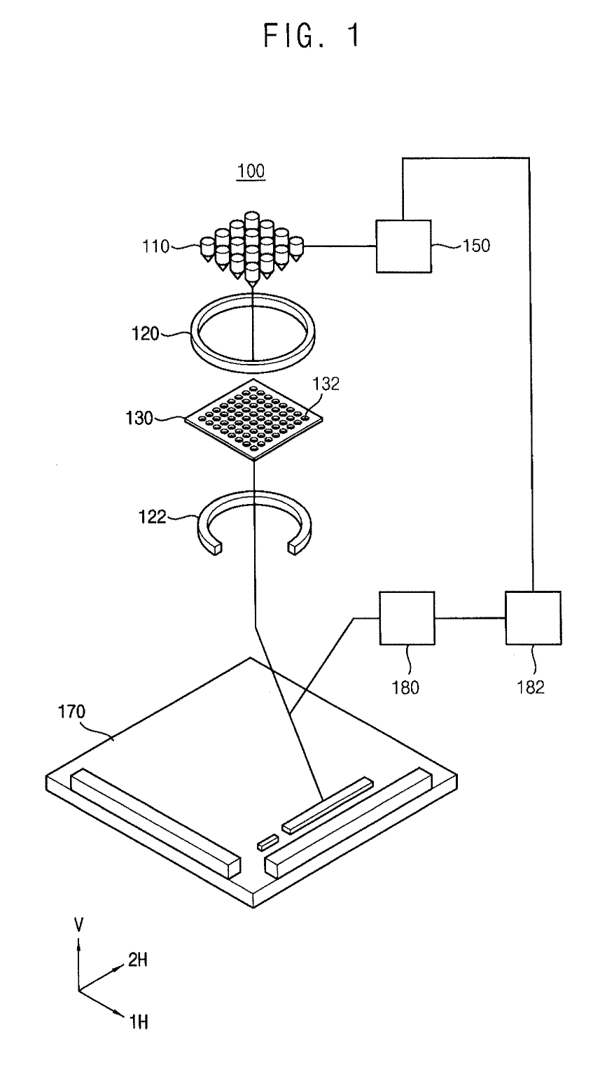

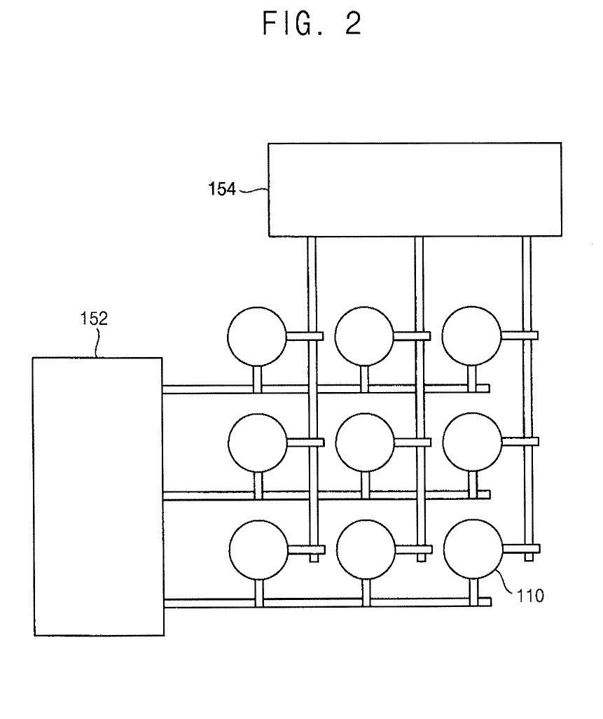

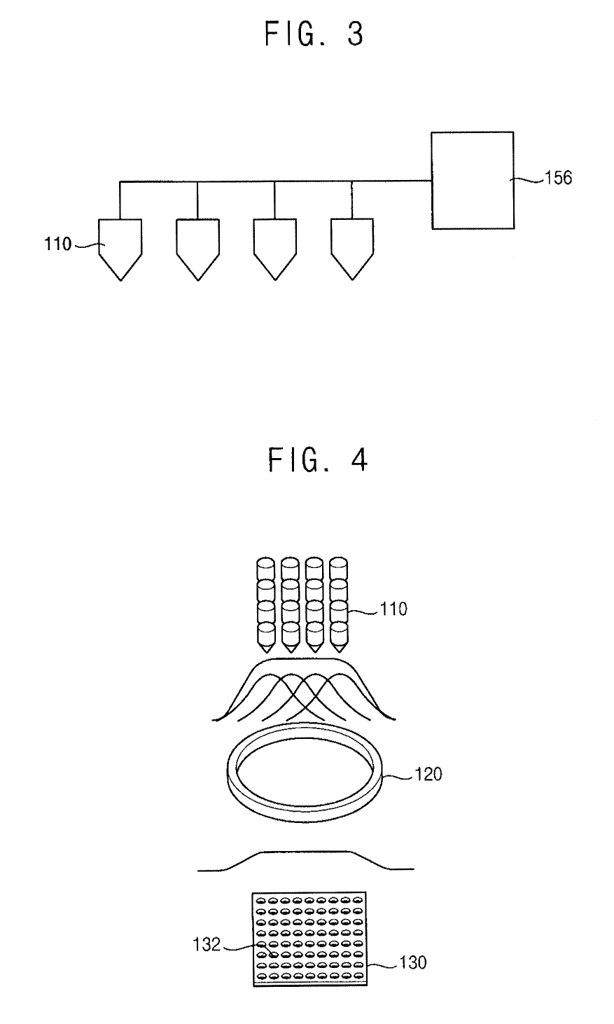

FIG. 1 illustrates a perspective view of an electron beam exposure apparatus in accordance with example embodiments. FIG. 2 illustrates a plan view of a position-adjusting unit of the electron beam exposure apparatus in FIG. 1. FIG. 3 illustrates a front view of the position-adjusting unit of the electron beam exposure apparatus in FIG. 1.

Referring to FIG. 1, an electron beam exposure apparatus 100 of this example embodiment may include a plurality of electron guns 110, a condenser lens 120, an aperture plate 130, and a position adjusting unit 150.

The electron guns 110 may be arranged, e.g., in a 1-D, 2-D, or 3-D array, over a stage 170 on which a substrate may be positioned. The electron guns 110 may emit electron beams toward the stage 170. In example embodiments, the electron guns 110 may include a filament. The electron beams emitted from the electron guns 110 may be accelerated by an accelerating electrode (not shown).

The condenser lens 120 may be arranged between the electron guns 110 and the stage 170. The condenser lens 120 may concentrate the electron beams emitted from the electron guns 110. A Gaussian distribution of the electron beams may be determined in accordance with the concentration of the condenser lens 120.

The aperture plate 130 may be arranged between the condenser lens 120 and the stage 170. The aperture plate 130 may have a plurality of apertures 132. The electron beams concentrated by the condenser lens 120 may pass through the apertures 132 to be directed toward the stage 170.

As illustrated in FIGS. 2 and 3, the positioning adjusting unit 150 may include first to third position adjusting members 152, 154, and 156.

In example embodiments, in order to form a resist pattern having a designed shape using the electron beams, as shown in FIG. 4, a combined condensed electron beam output from the condenser lens 120 has a relatively uniform intensity over the apertures 132. In order to realize a combined electron beam having such a relatively uniform intensity, electron beams having substantially a same intensity, e.g., Gaussian distributions having substantially equal peaks, emitted from the electron guns 110 arranged on a horizontal plane by substantially the same interval are incident on the condenser lens 120.

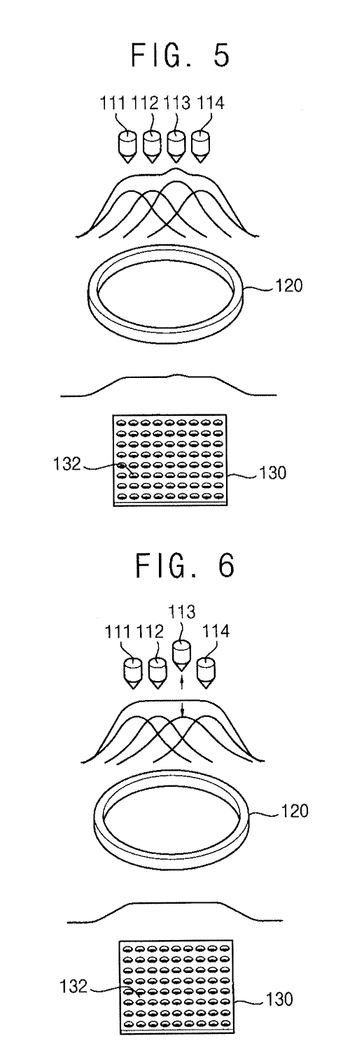

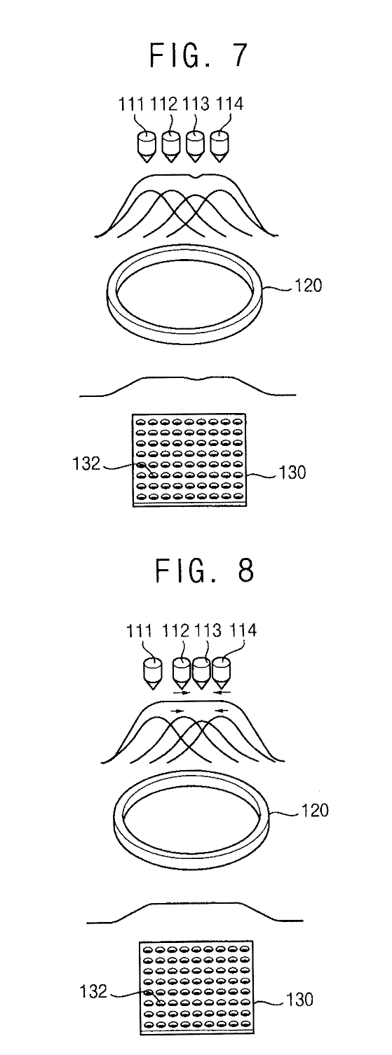

However, as shown in FIG. 5, the electron beams emitted from a first electron gun 111, a second electron gun 112, and a fourth electron gun 114 and concentrated by the condenser lens 120 may have substantially a same intensity. In contrast, the electron beam emitted from a third electron gun 113 and concentrated by the condenser lens 120 may have intensity higher than that of other electron beams. For example, the electron beam emitted from the third electron gun 113 may have a peak higher than that of other electron beams. In contrast, as shown in FIG. 7, the electron beam emitted from the third electron gun 113 and concentrated by the condenser lens 120 may have intensity lower than that of other electron beams. For example, the electron beam emitted from the third electron gun 113 may have a peak lower than that of other electron beams. As can be seen in FIGS. 5 and 7, the resultant combined electron beam output from the condenser lens 120 is not uniform. Thus, a resist pattern formed using the electron beams having different peaks may not have the designed shape.

Therefore, the electron beam exposure apparatus 100 of this example embodiment may include the position-adjusting unit 150. The position-adjusting unit 150 may be connected to the electron guns 110 to individually adjust positions of the electron guns 110. For example, when the electron beam emitted from the third electron gun 113 in FIG. 5 or FIG. 7 have an intensity different from that of other electron beams emitted from the first electron gun 111, the second electron gun 112, and the fourth electron gun 114, the position-adjusting unit 150 may adjust a position of the third electron gun 113 to provide the electron beam emitted from the third electron gun 113 with intensity substantially the same as that of other electron beams.

In example embodiments, referring to FIGS. 2 and 3 for the structure and FIGS. 6 and 8 for operation thereof, the position-adjusting unit 150 may include a first position-adjusting member 152, a second position adjusting member 154, and a third position-adjusting member 156. The first position-adjusting member 152 may individually move the electron guns 110 in a first horizontal direction (1H in FIG. 1). The second position-adjusting member 154 may individually move the electron guns 110 in a second horizontal direction (2H in FIG. 1) substantially perpendicular to the first horizontal direction. The third position-adjusting member 156 may individually move the electron guns 110 in a vertical direction (V in FIG. 1).

When the electron beam emitted from the third electron gun 113 has an intensity higher than that of other electron beams emitted from the first electron gun 111, the second electron gun 112, and the fourth electron gun 114, as shown in FIG. 5, the third position-adjusting member 156 may raise the third electron gun 113 to position the third electron gun 113 on a plane higher than that on which the first electron gun 111, the second electron gun 112, and the fourth electron gun 114 are positioned, as shown in FIG. 6. Thus, a distance between the third electron gun 113 and the condenser lens 120 may be longer than that between the first electron gun 111, the second electron gun 112, and the fourth electron gun 114 and the condenser lens 120, so that the peak of the electron beam emitted from the third electron gun 113 incident on the condenser lens 120 may be decreased. As a result, the electron beams emitted from the first electron gun 111, the second electron gun 112, the third electron gun 113, and the fourth electron gun 114 may have substantially the same intensity, so that the combined condensed beam output from the condenser lens 120 may have a substantially uniform intensity, as illustrated in FIG. 6.

When the electron beam emitted from the third electron gun 113 has an intensity lower than that of other electron beams emitted from the first electron gun 111, the second electron gun 112, and the fourth electron gun 114, as shown in FIG. 7, the first position-adjusting member 152 may move the second electron gun 112 and the fourth electron gun 114 toward the third electron gun 113 in the first horizontal direction to narrow an interval between the second electron gun 112 and the third electron gun 113, and an interval between the third electron gun 113 and the fourth electron gun 114, as shown in FIG. 8. High intensities of the electron beams emitted from the second electron gun 112 and the fourth electron gun 114 adjacent to the third electron gun 113 may be added to the intensity of the electron beam emitted from the third electron gun 113, so that the effective peak of the electron beam emitted from the third electron gun 113 may be increased. As a result, the condensed combined beam output from the condenser lens 120 may have uniform intensity, as illustrated in FIG. 8.

While the above examples illustrate how, according to embodiments, differences in intensities of electron beams maybe compensated, it will be apparent to those of skill in the art that the compensation may be realized in a variety of manners using the position adjusting unit to obtain a substantially uniform combined condensed beam. For example, when the electron beam emitted from the third electron gun 113 has an intensity higher than that of other electron beams emitted from the first electron gun 111, the second electron gun 112, and the fourth electron gun 114, the first position-adjusting member 152 may move the second electron gun 112 and the fourth electron gun 114 away from the third electron gun 113 in the first horizontal direction to increase an interval between the second electron gun 112 and the third electron gun 113, and an interval between the third electron gun 113 and the fourth electron gun 114. Low intensities of the electron beams emitted from the second electron gun 112 and the fourth electron gun 114 displaced from to the third electron gun 113 may be added to the intensity of the electron beam emitted from the third electron gun 113, so that the effective peak of the electron beam emitted from the third electron gun 113 may be decreased. As a result, the condensed combined electron beam output from the condenser lens 120 may have uniform intensity.

As another example, when the electron beam emitted from the third electron gun 113 has an intensity lower than that of other electron beams emitted from the first electron gun 111, the second electron gun 112, and the fourth electron gun 114, the third position-adjusting member 156 may drop the third electron gun 113 to position the third electron gun 113 on a plane lower than that on which the first electron gun 111, the second electron gun 112, and the fourth electron gun 114 may be positioned. A distance between the third electron gun 113 and the condenser lens 120 may be shorter than that between the first electron gun 111, the second electron gun 112, and the fourth electron gun 114 and the condenser lens 120, so that the peak of the electron beam emitted from the third electron gun 113 on the condenser lens 120 may be increased. As a result, the condensed combined electron beam output from the condenser lens 120 may have uniform intensity.

In example embodiments, the positions of the electron guns 110 may be individually adjusted using all or any one of the first to third position-adjusting members 152, 154, and 156 to provide the electron beams with the uniform intensity. Therefore, the position-adjusting unit 150 may include all of the first to third position-adjusting members 152, 154, and 156 or any one or two of the first to third position-adjusting members 152, 154, and 156.

In example embodiments, adjusting the positions of the electron guns 110 in accordance with the intensities of the electron beams may be performed based on database generated from numerous tests. For example, after positions of the electron guns 110 are changed in accordance with differences between the intensities of the electron beams, the intensities of the electron beams by the positions of the electron guns 110 may be measured. The measured intensities of the electron beams may be analyzed to set a position combination of the electron guns 110 having the best uniform intensity as an adjustment position of the electron guns 110 with respect to the differences between the intensities of the electron beams. The setting process may be performed several times under various intensity differences of the electron beams to finally set adjustment positions of the electron guns 110 by the intensity differences of the electron beams.

In example embodiments, the position-adjusting unit 150 may include a micrometer. The micrometer may adjust the positions of the electron guns 110 in micrometers. Additionally, the position-adjusting unit 150 may further include a piezoelectric element. The piezoelectric element may adjust the positions of the electron guns in a unit finer than that of the micrometer. Further, the position-adjusting unit 150 may include only the piezoelectric element.

Additionally, referring again to FIG. 1, the electron beam exposure apparatus 100 may further include a detector 180 and a controller 182. The detector 180 may measure the intensities of the electron beams passing through the apertures 132. The detector 180 may be arranged between the aperture plate 130 and the stage 170. In example embodiments, the detector 180 may include at least one faraday cup.

The controller 182 may store the intensities of the electron beams measured by the detector 180. The controller 182 may control operations of the position-adjusting unit 150 based on the stored intensities of the electron beams. That is, the controller 182 may control the operations of the position-adjusting unit 150 based on the intensities of the electron beams to provide the electron beams with the uniform intensity.

Additionally, a projector lens 122 may be arranged between the aperture plate 130 and the stage 170. The projector lens 122 may project the electron beams toward the stage 170.

According to example embodiments, the position-adjusting unit may selectively adjust the positions of the electron guns based on the intensities of the electron beams concentrated by the condenser lens to provide the electron beams passing through the apertures with the uniform intensity. Thus, a multi-shot obtained from the electron beams having the uniform intensity may also have uniform intensity, so that a resist pattern may have a desired shape. As a result, a pattern on the substrate formed using the resist pattern may have a designed shape.

In contrast, when a plurality of electron guns is used, intensities of the electron beams may be different from each other due to allowances of the electron guns. Further, when passing the single electron beam emitted from the single electron gun through a plurality of the apertures to form a multi-shot. However, energy of the electron beams may be greatly decreased when the single electron beam may pass through the apertures. While a radiation angle of the single electron beam may be narrowed in order to reduce the energy loss, the electron beams passing through the apertures may have different intensities. The multi-shot obtained from the electron beams having different intensities may not have uniform intensity. As a result, a resist pattern formed using the multi-shot may not have a designed shape

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. An electron beam exposure apparatus, comprising:
a plurality of electron guns configured to emit electron beams to a substrate;
a condenser lens arranged between the electron guns and the substrate, the condenser lens concentrating the electron beams;
a position-adjusting unit configured to individually adjust positions of the electron guns to provide the concentrated electron beam with a uniform intensity; and
an aperture plate arranged between the substrate and the condenser lens, the aperture plate having a plurality of apertures through which the concentrated electron beams pass.

2. The electron beam exposure apparatus as claimed in claim 1, wherein the position-adjusting unit comprises a first position-adjusting member configured to move the electron guns in a first horizontal direction.

3. The electron beam exposure apparatus as claimed in claim 2, wherein the position-adjusting unit further comprises a second position-adjusting member configured to move the electron guns in a second horizontal direction substantially perpendicular to the first horizontal direction.

4. The electron beam exposure apparatus as claimed in claim 1, wherein the position-adjusting unit comprises a position-adjusting member configured to move the electron guns in a vertical direction.

5. The electron beam exposure apparatus as claimed in claim 1, wherein the position-adjusting unit comprises a micrometer.

6. The electron beam exposure apparatus as claimed in claim 5, wherein the position-adjusting unit further comprises a piezoelectric element.

7. The electron beam exposure apparatus as claimed in claim 1, wherein the position-adjusting unit comprises a piezoelectric element.

8. The electron beam exposure apparatus as claimed in claim 1, further comprising a detector configured to detect intensities of the electron beams passing through the apertures.

9. The electron beam exposure apparatus as claimed in claim 8, further comprising a controller configured to store the intensities of the electron beams and to control operations of the position-adjusting unit based on the stored intensities of the electron beams.

10. An electron beam exposure apparatus, comprising:
a plurality of electron guns configured to emit electron beams to a substrate;
a condenser lens arranged between the electron guns and the substrate to concentrate the electron beams;
a position-adjusting unit configured to individually adjust positions of the electron guns to provide the concentrated electron beam with a uniform intensity;
an aperture plate arranged between the substrate and the condenser lens, the aperture plate having a plurality of apertures through which the concentrated electron beam pass;
a projector lens configured to project the electron beams toward the substrate;
a detector configured to detect intensities of the electron beams passing through the apertures; and
a controller configured to store the intensities of the electron beams and to control operations of the position-adjusting unit based on the stored intensities of the electron beams.

11. The electron beam exposure apparatus as claimed in claim 10, wherein the position-adjusting unit comprises:
a first position-adjusting member configured to move the electron guns in a first horizontal direction;
a second position-adjusting member configured to move the electron guns in a second horizontal direction substantially perpendicular to the first horizontal direction; and
a third position-adjusting member configured to move the electron guns in a vertical direction.

12. The electron beam exposure apparatus as claimed in claim 10, wherein the position-adjusting unit comprises a micrometer.

13. The electron beam exposure apparatus as claimed in claim 12, wherein the position-adjusting unit further comprises a piezoelectric element.

14. An electron beam exposure apparatus, comprising:
a plurality of electron guns configured to emit electron beams to a stage;
a condenser lens arranged between the electron guns and the stage, the condenser lens concentrating the electron beams;
a position-adjusting unit configured to individually adjust positions of the electron guns to provide the concentrated electron beam with a uniform intensity; and
an aperture plate arranged between the stage and the condenser lens, the aperture plate having a plurality of apertures on which the concentrated electron beam is incident.

15. The electron beam exposure apparatus as claimed in claim 14, wherein the position-adjusting unit comprises a first position-adjusting member configured to move the electron guns in a first horizontal direction.

16. The electron beam exposure apparatus as claimed in claim 15, wherein the position-adjusting unit further comprises a second position-adjusting member configured to move the electron guns in a second horizontal direction substantially perpendicular to the first horizontal direction.

17. The electron beam exposure apparatus as claimed in claim 16, wherein the position-adjusting unit comprises a position-adjusting member configured to move the electron guns in a vertical direction.

18. The electron beam exposure apparatus as claimed in claim 14, wherein the position-adjusting unit comprises a position-adjusting member configured to move the electron guns in a vertical direction.

19. The electron beam exposure apparatus as claimed in claim 14, wherein the plurality of electron guns is arranged in a 2-dimensional array.
